(19) United States
(12) Patent Application Publication
(10) Pub. No.: US 2018/0137929 A1
(43) Pub. Date: May 17, 2018

(54) WEAR SENSOR AND METHOD OF OPERATION FOR A MEMORY DEVICE

(71) Applicant: QUALCOMM Incorporated, San Diego, C (US)

(72) Inventors: Giby Samson, San Diego, CA (US); Erik Hedberg, Durham, NC (US); Francois Atallah, Raleigh, NC (US); Keith Bowman, Morrisville, NC (US)

(21) Appl. No.: 15/350,669

(22) Filed: Nov. 14, 2016

(51) Int. Cl. G11C 29/50; G11C 11/419

(52) U.S. Cl. CPC G11C 29/50012; G11C 11/419

(57) ABSTRACT

A device includes a first set of storage elements, a second set of storage elements, and a bias circuit configured to generate a test bias signal to bias the first set of storage elements and the second set of storage elements. The device further includes a sensor circuit configured to receive a first signal from at least a first storage element of the first set of storage elements in response to the test bias signal and to receive a second signal from at least a second storage element of the second set of storage elements in response to the test bias signal. The sensor circuit is further configured to generate a third signal having a delay characteristic indicating a wear difference between the first storage element and the second storage element.

### I. FIELD

The present disclosure is generally related to memory devices and more particularly to wear sensors for memory devices.

### II. DESCRIPTION OF RELATED ART

Memory devices enable users to store and retrieve data. Examples of memory devices include volatile memory devices and non-volatile memory devices. A non-volatile memory may retain data after a power-down event, and a volatile memory may lose data after a power-down event. An example of a volatile memory is a static random access memory (SRAM).

Writing data to storage elements of an SRAM device alters performance of the SRAM device due to “aging” of transistors of the SRAM device. As an illustrative example, a threshold voltage of a transistor may change based on a negative bias temperature instability (NBTI) effect due to physical wear resulting from operation of the transistor.

In some designs, mitigation of the eventual effects of aging transistors may be designed into a circuit by use of an increased supply voltage (or application of an “uplift margin”), which may be applied to transistors of a memory throughout the life of the memory, including prior to aging of the memory. Increasing the supply voltage consumes power and may accelerate aging, such as by increasing NBTI of a transistor due to additional “stress” caused by the uplift margin.

### III. SUMMARY

A device in accordance with aspects of the disclosure includes a sensor circuit coupled to a first set of storage elements and a second set of storage elements. In an illustrative example, the first set of storage elements corresponds to a set of “aging” storage elements (e.g., a column of storage elements that store data during operation of the device), and the second set of storage elements corresponds to a set of “non-aging” storage elements, such as a set of reference storage elements that are reserved for test processes.

During a test process, the device may generate a first signal (e.g., a first bit line drain current) using at least a first storage element of the first set of storage elements and may generate a second signal (e.g., a second bit line drain current) using at least a second storage element of the second set of storage elements. The device may increase a test bias voltage applied to complement bit lines of the device to cause one or more storage elements of the device to change (or “flip”) states. The sensor circuit may generate a third signal based on the first signal and the second signal. The third signal may indicate a delay characteristic that corresponds a delay between a state change of the first storage element and a state change of the second storage element.

The delay characteristic indicates an amount of “aging” of one or more transistors of the first storage element. For example, as a transistor of the first storage element is subject to negative-bias temperature instability (NBTI), the transistor may become “weaker” (e.g., due to change in a threshold voltage of the transistor). As a result, the transistor may “weaken” the first storage element so that the first storage element changes state sooner in response to the increased test bias voltage. By detecting a delay between state change of the first storage element and state change of the second storage element, the device may determine an amount of “aging” of one or more transistors of the first storage element. The device may include control circuitry that adjusts a supply voltage based on the amount of aging (e.g., to compensate for a change in threshold voltage of a transistor).

By adjusting the supply voltage based on the amount of aging, an uplift margin may be reduced or eliminated. For example, instead of applying the uplift margin at a factory based on a “worst-case” operating scenario, a device may adjust a supply voltage dynamically (e.g., during operation by an end user of the device). Further, dynamically adjusting the supply voltage may reduce aging that results from uplift margin (e.g., aging due to increased transistor stress caused by the uplift margin).

Further, by determining a reference signal (e.g., the second signal) dynamically, performance of the device may be improved as compared to a technique that retrieves stored reference information. To illustrate, certain other devices may compare transistor performance with stored information (e.g., NBTI information) to determine an amount of aging of transistors of a memory device. Such a technique may be inaccurate in some circumstances. For example, changes in transistor performance due to changes in temperature or voltage may reduce accuracy of such a technique. A device in accordance with the disclosure may “cancel” (or substantially cancel) effects of temperature or voltage variations by generating the first signal concurrently or substantially concurrently with generating the second signal.

A sensor circuit in accordance with aspects of the disclosure may be configured to generate a digital signal. To illustrate, the sensor circuit may include an exclusive-or (XOR) circuit that generates a square pulse signal having the delay characteristic. In an alternate implementation, the sensor circuit may be configured to output an oscillation signal having a frequency that indicates the amount of aging. For example, the sensor circuit may include a current-starved ring oscillator circuit configured to generate the oscillation signal. Use of a digital technique may simplify circuit design and circuit operation as compared to an analog-based technique.

In an illustrative example, a device includes a first set of storage elements and includes a second set of storage elements. The device further includes a bias circuit configured to generate a test bias signal to bias the first set of storage elements and the second set of storage elements. The device further includes a sensor circuit configured to receive a first signal from at least a first storage element of the first set of storage elements in response to the test bias signal and to receive a second signal from at least a second storage element of the second set of storage elements in response to the test bias signal. The sensor circuit is further configured to generate a third signal having a delay characteristic indicating a wear difference between the first storage element and the second storage element.

In another illustrative example, a device includes a set of storage elements configured to receive a supply voltage and a sensor circuit coupled to the set of storage elements. The sensor circuit is configured to receive a first signal from one or more storage elements of the set of storage elements and to generate a second signal having a frequency that indicates a magnitude of the first signal. The device further includes a control circuit coupled to the set of storage elements. The control circuit is configured to increase the supply voltage in response to the frequency of the second signal.

In another illustrative example, a method of operation of a device includes generating a first signal using at least one static random access memory (SRAM) storage element of a device. The method further includes generating a second signal using a reference SRAM storage element. A third signal having a delay characteristic is generated based on the first signal and the second signal. The delay characteristic indicates aging of one or more transistors of the at least one SRAM storage element. The method further includes increasing a supply voltage of the at least one SRAM storage element based on the delay characteristic.

One particular advantage provided by at least one of the disclosed examples is increased power savings and reduced transistor aging as compared to certain conventional aging compensation circuits. For example, certain conventional aging compensation circuits may operate using a voltage margin that is based on a “worst case” amount of aging. Instead of applying an uplift margin based on a “worst case” scenario, a device in accordance with aspects of the disclosure may dynamically set a supply voltage, such as by determining transistor aging at multiple times throughout operation of the device. As a result, a supply voltage may be reduced as compared to certain conventional aging compensation circuits, which may reduce power consumption and transistor aging associated with higher supply voltages. Other aspects, advantages, and features of the disclosure will become apparent after review of the entire application, including the following sections: Brief Description of the Drawings, Detailed Description, and the Claims.

### IV. BRIEF DESCRIPTION OF THE DRAWINGS

FIG. 1 is a diagram of an illustrative example of a device that includes a set of storage elements and a sensor circuit coupled to the set of storage elements.

FIG. 2 is a diagram of another illustrative example of a device that includes a set of storage elements and a sensor circuit coupled to the set of storage elements.

FIG. 3 is a diagram of an illustrative example of a system that includes the device of FIG. 2.

FIG. 4 is a flow chart of an illustrative example of a method of operation of the device of FIG. 1.

FIG. 5 is a block diagram of an illustrative example of an electronic device that includes the device of FIG. 1, the device of FIG. 2, or both.

### V. DETAILED DESCRIPTION

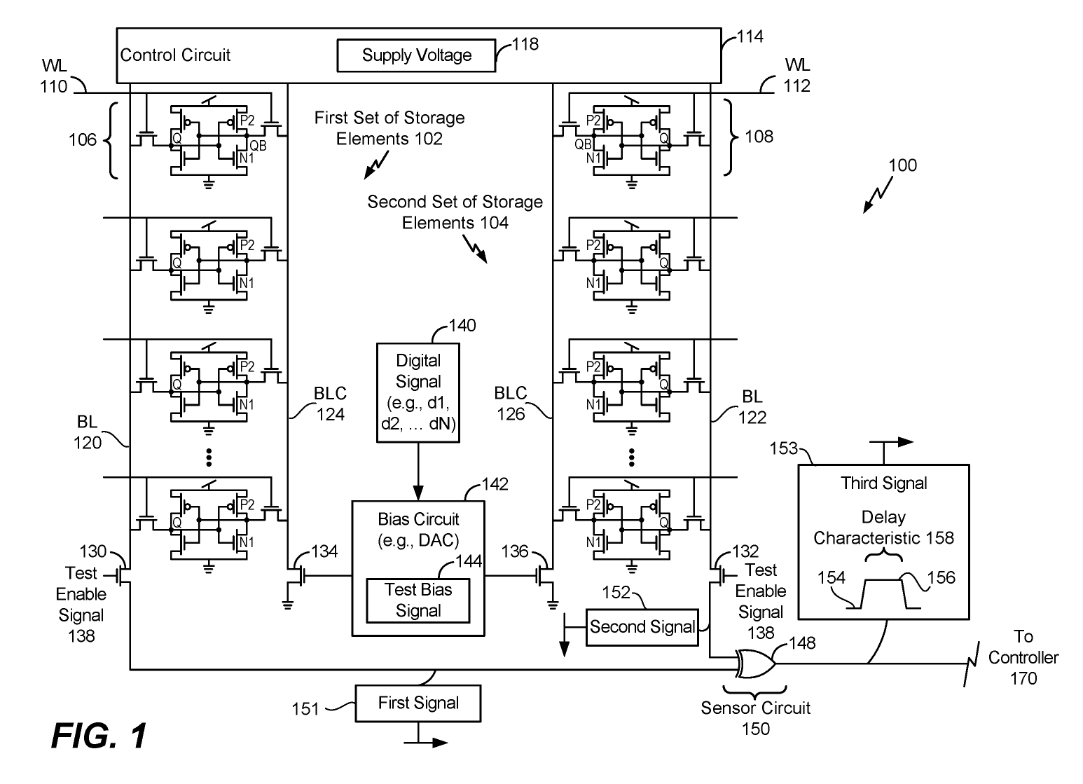

FIG. 1 depicts an illustrative example of a device 100. The device 100 includes a first set of storage elements 102 and a second set of storage elements 104. As an illustrative example, the sets of storage elements 102, 104 may be included in a static random access memory (SRAM) device. To further illustrate, the first set of storage elements 102 may be included in a particular column of the SRAM device, and the second set of storage elements 104 may be included in another column of the SRAM device. In an illustrative example, the device 100 is integrated within a cache of a processor. Alternatively, or in addition, the device 100 may be implemented in another device.

The first set of storage elements 102 may include a representative first storage element 106. In the illustrative example of FIG. 1, the first storage element 106 has a six-transistor (6T) configuration. For example, the first storage element 106 may include a transistor N1, such as an n-type metal-oxide-semiconductor field-effect transistor (nMOSFET). The first storage element 106 may further include a transistor P2, such as a p-type metal-oxide-semiconductor field-effect transistor (pMOSFET). The first storage element 106 also includes a node Q and a node QB. The transistors N1, P2 are coupled via the node QB.

The second set of storage elements 104 may include a representative second storage element 108. In the illustrative example of FIG. 1, the second storage element 108 has a 6T configuration. For example, the second storage element 108 may include a transistor N1, such as nMOSFET. The second storage element 108 may further include a transistor P2, such as a pMOSFET. The second storage element 108 also includes a node Q and a node QB. The transistors N1, P2 are coupled via the node QB.

In some examples, the first set of storage elements 102 corresponds to an “aging” set of storage elements that is used during non-test operation of the device 100. The second set of storage elements 104 may correspond to a “reference” (or “non-aging”) set of storage elements that is reserved for test processes (e.g., and that is not used during non-test operation of the device 100). In some examples, the second set of storage elements 104 enables detection of “aging” effects at the first set of storage elements 102, such as negative-bias temperature instability (NBTI), as an illustrative example.

The device 100 includes a first bit line 120 coupled to the first set of storage elements 102 and a second bit line 122 coupled to the second set of storage elements 104. A first complement bit line 124 may be coupled to the first set of storage elements 102, and a second complement bit line 126 may be coupled to the second set of storage elements 104.

A first access transistor 130 may be coupled to the first bit line 120, and a second access transistor 132 may be coupled to the second bit line 122. FIG. 1 also illustrates that a third access transistor 134 may be coupled to the first complement bit line 124, and a fourth access transistor 136 may be coupled to the second complement bit line 126.

The device 100 further includes a bias circuit 142 coupled to the access transistors 134, 136. In some implementations, the bias circuit 142 includes a digital-to-analog converter (DAC) circuit.

The device 100 also includes a sensor circuit 150 coupled to the access transistors 130, 132. In the illustrative example of FIG. 1, the sensor circuit 150 includes an exclusive-or (XOR) circuit 148 that is coupled to the access transistors 130, 132. In other implementations, the sensor circuit 150 may include one or more other circuits alternatively or in addition to the XOR circuit 148.

The device 100 may further include a control circuit 114. The control circuit 114 is coupled to the bit lines 120, 122 and to the complement bit lines 124, 126. The control circuit 114 is configured to provide a supply voltage 118 to storage elements of the sets of storage elements 102, 104. As an illustrative example, the control circuit 114 may be configured to provide the supply voltage 118 to pMOSFET transistors of the device 100, such as to the transistor P2 of the first storage element 106 and to the transistor P2 of the second storage element 108.

FIG. 1 also depicts that a first word line 110 may be coupled to the first storage element 106 and that a second word line 112 may be coupled to the second storage element 108. In some implementations, the word lines 110, 112 are coupled to the control circuit 114, and the control circuit 114 is configured to bias the word lines 110, 112.

During operation, the device 100 is configured to perform a test process targeting one or more storage elements, such as the first storage element 106, as an illustrative example. The test process may be performed to detect NBTI at one or more storage elements of the device 100, as an illustrative example. The test process may be performed by a manufacturer of the device 100, during operation by an end user of the device 100, in response to a trigger condition (e.g., upon power-up of an electronic device that includes the device 100), at another time, or any combination thereof.

Prior to performing the test process, the access transistors 130, 132 may be activated using a test enable signal 138. The test enable signal 138 may be provided by the control circuit 114 or by another circuit, such as by a controller 170 coupled to the device 100 or by a processor that includes the device 100, as illustrative examples. The control circuit 114 may set the word lines 110, 112 to a logic zero voltage. As a result, the bit lines 120, 122 may have a logic zero voltage (or may “float” to a logic zero voltage).

The sensor circuit 150 is configured to receive a first signal 151 from the bit line 120 and a second signal 152 from the second bit line 122. While the bit lines 120, 122 have a logic zero voltage, the signals 151, 152 may have a logic zero voltage. As a result, the XOR circuit 148 is configured to generate a third signal 153 having a first value, such as a logic zero value 154.

To initiate the test process, the control circuit 114 may be configured to write a value to the storage elements 106, 108. As an illustrative example, writing the value may include setting the nodes Q to a particular voltage (e.g., a logic zero voltage) and setting nodes QB to another voltage (e.g., a logic one voltage) using the word lines 110, 112, the bit lines 120, 122, and the complement bit lines 124, 126. As used herein, a storage element may be referred to as storing a logic zero value if the node Q has a logic zero voltage (and the node QB has a logic one voltage) and as storing a logic one value if the node Q has a logic one voltage (and the node QB has a logic zero voltage).

The value written to the first storage element 106 may “stress” one or more transistors of the first storage element 106. Stress may occur at a transistor when a gate terminal and source and drain terminals of the transistor are subject to different bias voltages. For example, stress at the transistor N1 may occur when a gate terminal of the transistor N1 is subject to a logic one voltage and when source and drain terminals of the transistor N1 are subject to a logic zero voltage. As another example, stress at the transistor P2 may occur when a gate terminal of the transistor P2 is subject to a logic zero voltage and when source and drain terminals of the transistor P2 are subject to a logic one voltage.

The bias circuit 142 is configured to generate a test bias signal 144 (e.g., an analog signal) to bias the first set of storage elements 102 and the second set of storage elements 104 based on a digital signal 140. The bias circuit 142 may be configured to receive the digital signal 140 from the controller 170 or from a processor that includes the device 100, as illustrative examples.

To further illustrate, the bias circuit 142 may include a DAC circuit configured to receive the digital signal 140 (e.g., from the controller 170) and to generate the test bias signal 144 based on the digital signal 140. During a test process, the digital signal 140 may have a digital value that is adjustable based on a range of digital values d1, d2, dN (where N is a positive integer). As an illustrative example, the digital signal 140 may include six bits, and the DAC circuit may have a 64-level resolution (where N=64). In this example, the digital signal 140 may be adjusted from d1=000000 to d2=000001 and from d2=000001 to d3=000010, as illustrative examples.

Increasing the value of the digital signal 140 may increase a voltage level of the test bias signal 144. In a non-limiting illustrative example, incrementing the value of the digital signal 140 increases the voltage level of the test bias signal 144 by approximately 15 millivolts (mV).

During the test process, the digital value of the digital signal 140 may be increased until a particular value of the digital signal 140 causes the first storage element 106 to “flip” states (e.g., from storing a logic zero value to storing a logic one value). For example, to determine aging of the transistor P2 of the first storage element 106, the digital value of the digital signal 140 may be increased while the node QB has a logic one value and while the transistor P2 provides a supply voltage to the first complement bit line 124. The digital value of the digital signal 140 may be increased until the third access transistor 134 “overpowers” the transistor P2 of the first storage element 106 by coupling the first complement bit line 124 to ground, resulting in a logic zero voltage at the node QB and a logic one voltage at the node Q (and “flipping” the state of the first storage element 106). In this case, increasing the digital value of the digital signal 140 increases the test bias signal 144 to increase a magnitude of a current through the first complement bit line 124 and the third access transistor 134. The magnitude of the current may be increased (via the digital value of the digital signal 140) until the magnitude of the current is sufficient to “flip” the state of the first storage element 106 by deactivating the transistor P2 of the first storage element 106. As the transistor P2 ages, smaller digital values of the digital signal 140 may “flip” the state of the first storage element 106.

To further illustrate, a particular example of the test process is described with reference to certain illustrative digital values of the digital signal 140. For example, the controller 170 may provide the digital value d1 of the digital signal 140 to the bias circuit 142. After the controller 170 provides the digital value d1 of the digital signal 140 to the bias circuit 142, the control circuit 114 may activate the first word line 110 and the second word line 112. In an illustrative example, one or both of the word lines 110, 112 are overdriven using a voltage greater than the supply voltage 118 (e.g., in order to reduce a series resistance associated with an access transistor of a storage element). Because the storage elements 106, 108 store a logic zero value, activating the word lines 110, 112 results in a logic zero voltage at the bit lines 120, 122. As a result, the first bit line 120 and the second bit line 122 may remain at a logic zero voltage, and third signal 153 may remain at the logic zero value 154.

In some examples, the third signal 153 is provided to the controller 170. The controller 170 may detect the logic zero value 154 of the third signal 153. In response to detecting the logic zero value 154 of the third signal 153, the controller 170 may increase the digital value of the digital signal 140 (e.g., from the digital value d1 to the digital value d2).

In some cases, the digital value d2 may cause the first complement bit line 124 to “flip” the state of the first storage element 106. For example, due to an aging effect (e.g., an NBTI effect) associated with one or more transistors of the first storage element 106, the test bias signal 144 may cause the state of the first storage element 106 to “flip.” As a result, the node Q may have a logic one voltage, and the node QB may have a logic zero voltage. In this case, the state of the first storage element 106 “flips” from a logic zero value to a logic one value. In an implementation where the second set of storage elements 104, the digital value d2 may be insufficient to “flip” the state of the second storage element 108 (e.g., due to less NBTI at the second storage element 108 as compared to the first storage element 106).

Testing may continue with deactivating the word lines 110, 112, incrementing the digital signal 140 to the digital value d2, and providing the digital value d2 to the bias circuit 142. After providing the digital value d2 of the digital signal 140 to the bias circuit 142, the control circuit 114 may activate the first word line 110 and the second word line 112. In an illustrative example, one or both of the word lines 110, 112 are overdriven using a voltage greater than the supply voltage 118 (e.g., in order to reduce a series resistance associated with an access transistor of a storage element). Because the first storage element 106 stores a logic one value, activating the first word line 110 results in a logic one voltage at the first bit line 120. In addition, because the second storage element 108 stores a logic zero value, activating the second word line 112 results in a logic zero voltage at the second bit line 122. As a result, the first bit line 120 may have a logic one voltage, and the second bit line 122 may have a logic zero voltage. Accordingly, the sensor circuit 150 may be configured to transition the third signal 153 from the logic zero value 154 to a second value, such as a logic one value 156.

While the third signal 153 has the logic one value 156, the controller 170 may continue to increase the digital value of the digital signal 140 until the state of the second storage element 108 is “flipped” based on a magnitude of a current through the fourth access transistor 136. To illustrate, increasing the digital signal 140 from the digital value d2 to a digital value d3 may be insufficient to increase the magnitude of the current such that the state of the node QB of the second storage element 108 is changed from a logic one value to a logic zero value (e.g., due to reduced NBTI at the second storage element 108 as compared to the first storage element 106). As a result, the third signal 153 may retain the logic one value 156.

As another example, the controller 170 may increase the digital signal 140 from the digital value d3 to a digital value d4. In an illustrative example, the digital value d4 may cause the test bias signal 144 to “flip” the state of the second storage element 108 from a logic zero value to a logic one value. As a result, the second signal 152 may have a logic one voltage.

The sensor circuit 150 is configured to transition the third signal 153 from the logic one value 156 to the logic zero value 154 based on the logic one voltage of the second signal 152. As a result, the third signal 153 has a delay characteristic 158. The delay characteristic 158 indicates a wear difference between the first storage element 106 and the second storage element 108. The wear difference may indicate an amount of NBTI associated with one or more transistors of the first storage element 106.

To illustrate, as the first storage element 106 is used during operation of the device 100, the first storage element 106 is subject to physical wear, which may cause an NBTI effect at the first storage element 106. Aging of the first storage element 106 may “weaken” one or more transistors of the first storage element 106. As a result, lower values of the digital signal 140 may “flip” the stage of the first storage element 106 during a test process. Thus, a larger delay characteristic 158 may indicate more aging of the first storage element 106 (relative to the second storage element 108), and a smaller delay characteristic 158 may indicate less aging of the first storage element (relative to the second storage element 108).

Accordingly, the sensor circuit 150 may be configured to transition the third signal 153 from the logic zero value 154 to the logic one value 156 in response to a state change of the first storage element 106 based on a first value of the digital signal 140 (e.g., the digital value d2, or another value) at a first time. The sensor circuit 150 may be further configured to transition the third signal 153 from the logic one value 156 to the logic zero value 154 in response to a state change of the second storage element 108 based on a second value of the digital signal 140 (e.g., the digital value d4, or another value) at a second time after the first time.

The controller 170 may monitor digital values of the digital signal 140 that cause transitions of the third signal 153. Continuing with the foregoing example, the digital value d2 may cause a first transition of the third signal 153 from the logic zero value 154 to the logic one value 156, and the digital value d4 may cause a second transition of the third signal 153 from the logic one value 156 to the logic zero value 154. In this example, the controller 170 may store an indication of the digital values d2, d4.

The controller 170 may be configured to determine whether the delay characteristic 158 satisfies a threshold. For example, the controller 170 may determine a difference between the digital values d2, d4 and may determine whether the difference satisfies the threshold.

If the difference satisfies the threshold, the controller 170 may be configured to cause the control circuit 114 to increase the supply voltage 118 (e.g., to compensate for aging of storage elements of the device 100, such as aging due to NBTI). In this example, the control circuit 114 is configured to increase the supply voltage 118 in response to the delay characteristic 158 satisfying the threshold. Alternatively, if the difference fails to satisfy the threshold, the controller 170 may refrain from increasing the supply voltage 118 (e.g., as a result of a relatively small amount of aging of the first storage element 106 being indicated by the delay characteristic 158).

In an illustrative example, the sensor circuit 150 is configured to determine (e.g., measure) aging of one or more transistors of the device 100 dynamically (or “on-the-fly”). As used herein, dynamically determining transistor aging may refer to generation of the third signal 153 based on in situ generation of the first signal 151 and the second signal 152. The sensor circuit 150 may be configured to dynamically determine transistor aging without accessing stored reference information. By determining transistor aging without using stored reference information, transistor aging may be determined irrespective of a prior condition of the device 100, such as a temperature and voltage condition. In the example of FIG. 1, the second signal 152 may be generated concurrently (or substantially concurrently) with the first signal 151 during the test process. As a result, the test process may “cancel out” (or substantially cancel out) effects of temperature and voltage variations (because the temperature and voltage variations have a similar effect on the signals 151, 152).

In some implementations, transistors of the first set of storage elements 102 may age based on a “permanent” aging characteristic and a “temporary” aging characteristic that exists for a short amount of time after writing to a storage element. The device 100 may be configured to determine an amount of temporary aging by generating the first signal 151 soon after writing data to the first storage element 106, waiting a particular interval, and then re-testing the first storage element 106 (e.g., after temporary aging at the first set of storage elements 102 has “settled”). By testing the first storage element 106 during “settled” and “unsettled” conditions, the controller 170 may determine an amount of temporary aging of the first storage element 106. In some applications, the controller 170 may be configured to perform one or more operations based on temporary aging or permanent aging, such as by adjusting the supply voltage 118 based on permanent aging (and by ignoring temporary aging when adjusting the supply voltage 118).

It is noted that certain aspects of FIG. 1 are illustrative and non-limiting. For example, although the test process described with reference to FIG. 1 is illustrated using one “aging” storage element (the first storage element 106), it should be appreciated that a test process may be performed using one or more other storage elements of the device 100 alternatively or in addition to the first storage element 106 (either in parallel or serially with respect to use of the first storage element 106).

Although NBTI has been provided as an example of “aging” of transistors for illustration, it should be appreciated that other aging may occur (alternatively or in addition to NBTI). Other examples of aging include positive-bias temperature instability (PBTI) and hot carrier injection (HCl), as illustrative examples. To further illustrate, a test process may be performed to detect a PBTI effect that alters a threshold voltage of one or more transistors, such as the transistor N1 of the first storage element 106. Detecting the PBTI effect associated with the transistor N1 may be performed alternatively or in addition to detecting a PBTI effect associated with the transistor P2.

Although certain examples of testing have been described with reference to the first storage element 106, it should be appreciated that multiple storage elements may be tested (concurrently or sequentially) alternatively or in addition to testing of the first storage element 106. For example, two or more storage elements of the first group of storage elements 102 may be tested (concurrently or sequentially). In an illustrative example, the first group of storage elements 102 includes a column of storage elements that are tested (concurrently or sequentially). Further, multiple columns of storage elements may be tested (concurrently or sequentially).

One or more aspects described with reference to FIG. 1 may improve operation of a memory device, such as the device 100. For example, instead of applying an uplift margin based on a “worst case” scenario, the supply voltage 118 may be set dynamically. As a result, power consumption and transistor aging may be reduced at the device 100.

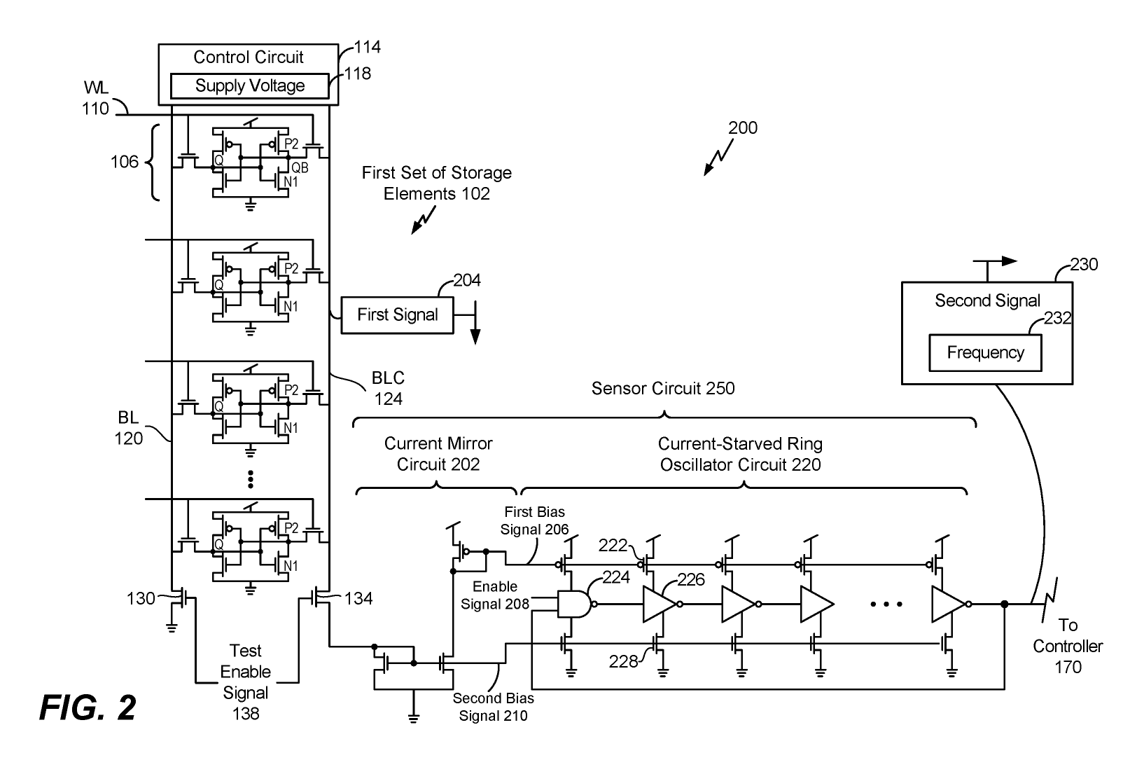

Referring to FIG. 2, another example of a device is depicted and generally designated 200. One or more aspects of the device 200 may be as described with reference to the device 100 of FIG. 1. For example, the device 200 includes the first set of storage elements 102. The first set of storage elements 102 includes the first storage element 106. The first word line 110 may be coupled to the first storage element 106. In some implementations, the device 200 may include a register file that includes the first set of storage elements 102. Alternatively, or in addition, the device 200 may be implemented in another device.

The device 200 may further include the control circuit 114. The control circuit 114 may be coupled to the first set of storage elements 102. The control circuit 114 may be configured to provide the supply voltage 118 to certain transistors of the first set of storage elements 102 (e.g., to p-type transistors, such as the transistor P2).

The first bit line 120 may be coupled to the first set of storage elements 102 and to the first access transistor 130. The first complement bit line 124 may be coupled to the first set of storage elements 102 and to the third access transistor 134. The access transistors 130, 134 may be coupled to receive the test enable signal 138.

The device 200 also includes a sensor circuit 250 coupled to the third access transistor 134. In the example of FIG. 2, the sensor circuit 250 includes a current mirror circuit 202 and a current-starved ring oscillator circuit 220.

The current mirror circuit 202 is coupled to the first complement bit line 124 via the third access transistor 134. The current mirror circuit 202 is further coupled to the current-starved ring oscillator circuit 220.

The current-starved ring oscillator circuit 220 may include a not- and (NAND) circuit 224 and a set of inverter circuits, such as a representative inverter circuit 226. The inverter circuit 226 may be coupled to a transistor 222 and to a transistor 228. An output of the current starved ring oscillator circuit 220 may be coupled to the controller 170.

During operation, the device 200 is configured to perform a test process targeting one or more storage elements, such as the first storage element 106, as an illustrative example. The test process may be performed to detect NBTI at one or more storage elements of the device 200, as an illustrative example. The test process may be performed by a manufacturer of the device 200, during operation by an end user of the device 200, in response to a trigger condition (e.g., upon power-up of an electronic device that includes the device 200), at another time, or any combination thereof.

Prior to performing the test process, the access transistors 130, 134 may be activated using the test enable signal 138. The test enable signal 138 may be provided by the control circuit 114 or by another circuit, such as by the controller 170 or by a processor that includes the device 200, as illustrative examples. The control circuit 114 may set the first word line 110 to a logic zero voltage. As a result, the first bit line 120 may have a logic zero voltage (or may “float” to a logic zero voltage). The NAND circuit 224 may receive an enable signal 208.

During the test process, the control circuit 114 may be configured to write a particular value to one or more storage elements of the first set of storage elements 102 (e.g., to the first storage element 106). In some examples, the particular value corresponds to a logic zero value (e.g., so that the node Q of the first storage element 106 has a logic zero voltage and so that the node QB of the first storage element 106 has a logic one voltage).

The sensor circuit 250 is configured to receive a first signal 204 from one or more storage elements of the set of storage elements 102. For example, after writing the particular value to the first storage element 106, the control circuit 114 may provide a logic one voltage to the first word line 110 to activate the first word line 110. Upon providing the logic one voltage to the first word line 110, the logic one voltage at the node QB of the first storage element 106 may create the first signal 204. The current mirror circuit 202 may be configured to receive the first signal 204 from the first bit line 120 via the third access transistor 134.

The first signal 204 has a magnitude that indicates aging of one or more transistors of the first storage element 106. For example, as a p-type transistor of the first storage element 106 “ages,” NBTI at the p-type transistor may increase. As a result, “strength” of the p-type transistor may decrease (e.g., due to physical wear), reducing the magnitude of the first signal 204.

The current mirror circuit 202 is configured to generate a first bias signal 206 and a second bias signal 210 based on the first signal 204. For example, the first bias signal 206 may have a first voltage that is based on the magnitude of the first signal 204, and the second bias signal 210 may have a second voltage that is based on the magnitude of the first signal 204.

The sensor circuit 250 is configured to generate a second signal 230 having a frequency 232 that indicates the magnitude of the first signal 204. For example, the current-starved ring oscillator circuit 220 may be configured to receive the bias signals 206, 210 and to generate the second signal 230 based on the bias signals 206, 210. The frequency 232 may indicate NBTI associated with one or more transistors of the first set of storage elements 106.

To illustrate, a greater magnitude of the first signal 204 may increase voltage of the first bias signal 206 and may decrease voltage of the second bias signal 210. The voltages of the bias signals 206, 210 may determine an amount of “current starving” of the current-starved ring oscillator circuit 220. For example, as the voltage of the first bias signal 206 decreases, the transistor 222 may provide more voltage to the inverter circuit 226 (e.g., “pulling up” an output of the inverter circuit 226 more rapidly). As another example, as the voltage of the second bias signal 210 increases, the transistor 228 may “pull down” the output of the inverter circuit 226 more rapidly. As a result, the frequency 232 of the second signal 230 is based on the magnitude of the first signal 204.

In some implementations, the controller 170 is coupled to receive the second signal 230. The controller 170 may be configured to cause the control circuit 114 to adjust the supply voltage 118 based on the frequency 232 of the second signal 230. For example, if the frequency 232 fails to satisfy a threshold frequency, the controller 170 may detect aging (e.g., NBTI) of one or more transistors of the first storage element 106. As a result, the controller 170 may provide a control signal to the control circuit 114 to cause the control circuit 114 to increase the supply voltage 118. The control circuit 114 is configured to increase the supply voltage 118 in response to the frequency 232 of the second signal 230 (e.g., based on the control signal provided by the controller 170).

In an illustrative example, the sensor circuit 250 is configured to determine (e.g., measure) aging of one or more transistors of the device 200 dynamically (or “on-the-fly”). As used herein, dynamically determining transistor aging may refer to generation of the second signal 230 based on in situ generation of the first signal 204. The sensor circuit 250 may be configured to dynamically determine transistor aging without accessing stored reference information. By determining transistor aging without using stored reference information, transistor aging may be determined irrespective of a prior condition of the device 200, such as a temperature and voltage condition.

In some cases, the device 200 of FIG. 2 may be employed in applications where aging is to be measured or detected with less “resolution” as compared to the example of FIG. 1. For example, the sensor circuit 250 of FIG. 2 may be configured to detect larger changes in transistor threshold voltage as a result of transistor aging. In some cases, the sensor circuit 150 of FIG. 1 may be to detect a fine amount of transistor aging, and the device 200 of FIG. 2 may be used to detect a coarse amount of transistor aging.

One or more aspects described with reference to FIG. 2 may improve operation of a memory device, such as the device 200. For example, instead of applying an uplift margin based on a “worst case” scenario, the supply voltage 118 may be set dynamically. As a result, power consumption and transistor aging may be reduced at the device 200.

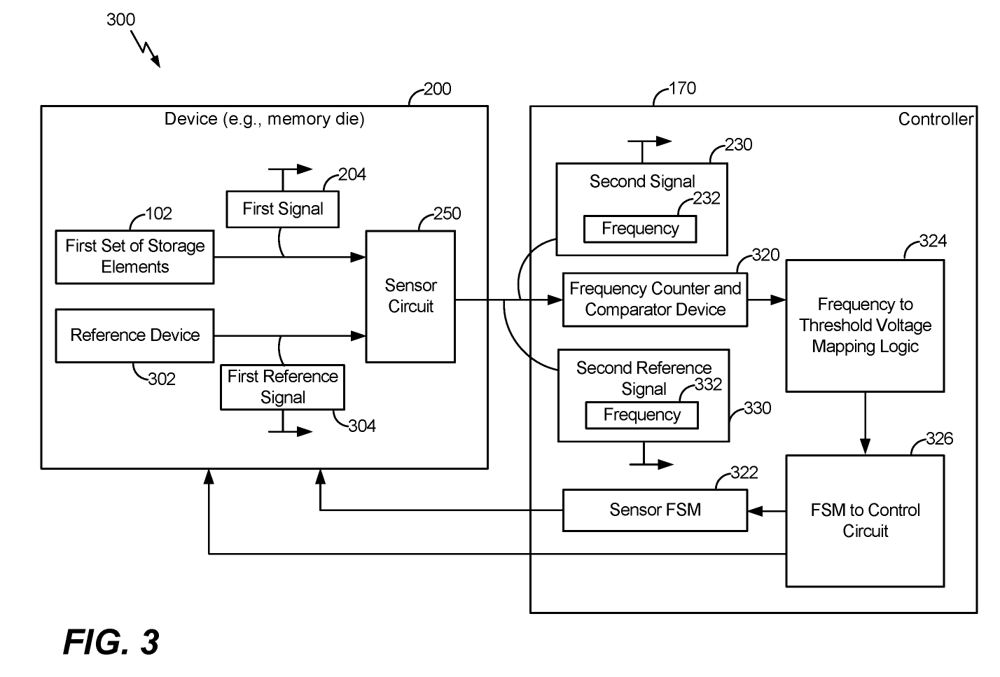

Referring to FIG. 3, an illustrative example of a system is depicted and generally designated 300. The system 300 includes the device 200 (e.g., a memory die) and the controller 170. The device 200 is coupled to the controller 170.

The device 200 includes the first set of storage elements 102 and a reference device 302. In some implementations, the reference device 302 includes the second set of storage elements 106 of FIG. 1. The sensor circuit 250 may be a device that is coupled to the first set of storage elements 102 and the reference device 302. In an illustrative example, the reference device 302 is located proximate to (e.g., adjacent to) the first set of storage elements 102. For example, the first set of storage elements 102 and the second set of storage elements 104 may correspond to adjacent columns of a memory array.

The controller 170 may include a frequency counter and comparator device 320. The controller 170 may further include a frequency to threshold voltage mapping logic 324 and a finite state machine (FSM) to control circuit 326. The controller 170 may also include a sensor FSM 322 coupled to the device 200.

During operation, the sensor FSM 322 may be configured to initiate a test process to determine an amount of aging of the first set of storage elements 102. For example, the sensor FSM 322 may be configured to assert the test enable signal 138, the enable signal 208, or both.

During the test process, the first set of storage elements 102 may be configured to generate the first signal 204, and the reference device 302 may be configured to generate a first reference signal 304. The sensor circuit 250 may be configured to generate the second signal 230 based on the first signal 204 and to generate a second reference signal 330 based on the first reference signal 304. The second signal 230 has the frequency 232, and the second reference signal 330 has a frequency 332.

Depending on the particular example, the device 200 may be configured to generate the second signal 230 and the second reference signal 330 concurrently or sequentially. In an example of a concurrent technique, the sensor circuit 250 may include multiple “copies” of the current mirror circuit 202 and the current-starved ring oscillator circuit 220 to enable generation of the second signal 230 and the second reference signal 330 in parallel. Concurrent generation of the second signal 230 and the second reference signal 330 may “cancel out” (or substantially cancel out) effects of temperature and voltage variations (because the temperature and voltage variations have a similar effect on the signals 151, 152). In an example of a sequential technique, the current mirror circuit 202 and the current-starved ring oscillator circuit 220 may be configured to generate the second signal 230 and the second reference signal 330 sequentially. A sequential technique may enable a design to avoid duplication of circuitry (e.g., by avoiding multiple “copies” of the sensor circuit 250 that operate in parallel).

The frequency counter and comparator device 320 may be configured to receive the second signal 230 and the second reference signal 330. The frequency counter and comparator device 320 may include one or more frequency counters configured to determine a first value corresponding to the frequency 232 and to determine a second value corresponding to the frequency 332. The frequency counter and comparator device 320 may include a comparator configured to compare the first value and the second value to determine a difference between the first value and the second value. The frequency counter and comparator device 320 may be configured to provide an indication of the difference to the frequency to threshold voltage mapping logic 324.

The frequency to threshold voltage mapping logic 324 may be configured to determine (or estimate) a threshold voltage of one or more transistors of one or more storage elements of the set of storage elements 102 based on the indication provided by the frequency counter and comparator device 320. To illustrate, if the difference between the first value and the second value satisfies a threshold, the frequency to threshold voltage mapping logic 324 may detect aging (e.g., NBTI) of the one or more transistors. Aging of a transistor may affect (e.g., “shift”) a threshold voltage of the transistor. Accordingly, the frequency to threshold voltage mapping logic 324 may determine (or estimate) an amount of threshold voltage “shift” of the transistor based on the difference between the first value and the second value.

In some implementations, the frequency to threshold voltage mapping logic 324 may be configured to access the FSM to control circuit 326 based on the estimated threshold voltage. The FSM to control circuit 326 may be configured to adjust the supply voltage 118 of FIGS. 1 and 2 based on the estimated threshold voltage. For example, if the estimated threshold voltage has increased, the FSM to control circuit 326 may access the control circuit 114 of FIGS. 1 and 2 to cause the control circuit 114 to increase the supply voltage 118.

One or more aspects described with reference to FIG. 3 may improve operation of a memory device, such as the device 200. For example, instead of applying an uplift margin based on a “worst case” scenario, the supply voltage 118 may be set dynamically. As a result, power consumption and transistor aging may be reduced at the system 300.

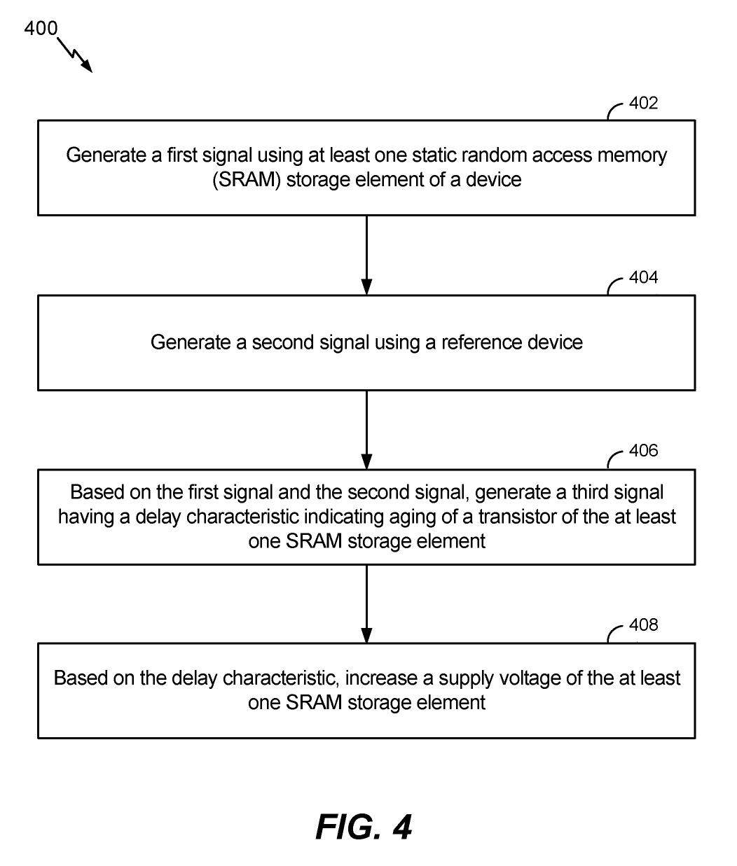

Referring to FIG. 4, an illustrative example of a method of operation of a device is depicted and generally designated 400. The method 400 may be performed at the device 100, as an illustrative example.

The method 400 includes generating a first signal using least one static random access memory (SRAM) storage element of a device, at 402. For example, the first signal 151 may be generated at the first bit line 120 using the first storage element 106 of the device 100.

The method 400 further includes generating a second signal using a reference SRAM storage element, at 404. For example, the second signal 152 may be generated using the second storage element 108.

The method 400 further includes generating a third signal having a delay characteristic based on the first signal and the second signal, at 406. The delay characteristic indicates aging of one or more transistors of the at least one SRAM storage element. For example, the third signal 153 has the delay characteristic 158. The delay characteristic 158 may indicate aging of the transistor P2 of the first storage element 106, aging of another transistor, or a combination thereof. In an illustrative example, the third signal 153 is generated using the XOR circuit 148. The delay characteristic 158 may correspond to a difference between a first transition of the first signal 151 from a first value (e.g., the logic zero value 154) to a second value (e.g., the logic one value 156) and a second transition of the second signal 152 from the first value to the second value.

The method 400 further includes increasing a supply voltage of the at least one SRAM storage element based on the delay characteristic, at 408. For example, the control circuit 114 may increase the supply voltage 118 based on the delay characteristic 158.

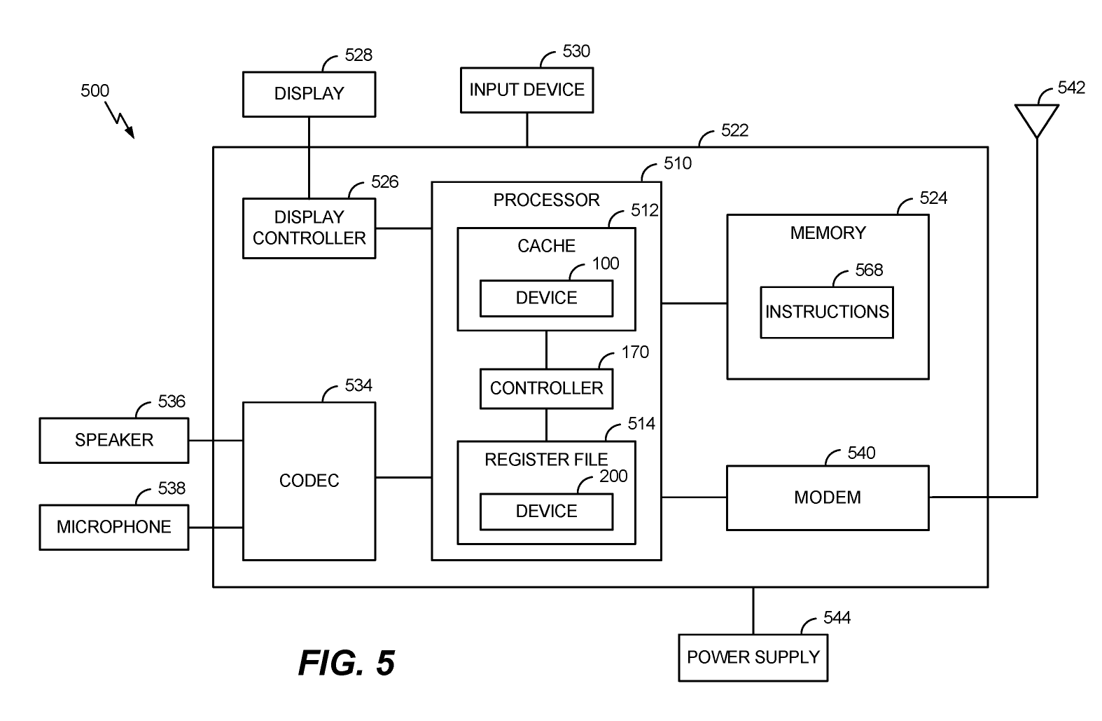

Referring to FIG. 5, a block diagram of a particular illustrative example of an electronic device is depicted and generally designated 500. The electronic device 500 may correspond to a mobile device (e.g., a cellular phone), a computer (e.g., a server, a laptop computer, a tablet computer, or a desktop computer), an access point, a base station, a wearable electronic device (e.g., a personal camera, a head-mounted display, or a watch), a vehicle control system or console, an autonomous vehicle (e.g., a robotic car or a drone), a home appliance, a set top box, an entertainment device, a navigation device, a personal digital assistant (PDA), a television, a monitor, a tuner, a radio (e.g., a satellite radio), a music player (e.g., a digital music player or a portable music player), a video player (e.g., a digital video player, such as a digital video disc (DVD) player or a portable digital video player), a robot, a healthcare device, another electronic device, or a combination thereof.

The electronic device 500 includes one or more processors, such as a processor 510. The processor 510 may include a digital signal processor (DSP), a central processing unit (CPU), a graphics processing unit (GPU), another processing device, or a combination thereof.

The electronic device 500 may include the device 100 of FIG. 1, the device 200 of FIG. 2, the system 300 of FIG. 3, or a combination thereof. In the illustrative example of FIG. 5, the electronic device 500 includes a cache 512 and a register file 514. The cache 512 may include the device 100, and the register file 514 may include the device 200. FIG. 5 further illustrates that the processor 510 may include the controller 170. The controller 170 may be coupled to the cache 512 and to the register file 514. It should be appreciated that the example of FIG. 5 is illustrative and that other examples are also within the scope of the disclosure.

The electronic device 500 may further include one or more memories, such as a memory 524. The memory 524 may be coupled to the processor 510. The memory 524 may include random access memory (RAM), magnetoresistive random access memory (MRAM), flash memory, read-only memory (ROM), programmable read-only memory (PROM), erasable programmable read-only memory (EPROM), electrically erasable programmable read-only memory (EEPROM), one or more registers, a hard disk, a removable disk, a compact disc read-only memory (CD-ROM), another memory device, or a combination thereof.

The memory 524 may store instructions 568. The instructions 568 may be executable by the processor 510 to perform, initiate, or control one or more operations described herein.

A coder/decoder (CODEC) 534 can also be coupled to the processor 510. The CODEC 534 may be coupled to one or more microphones, such as a microphone 538. FIG. 5 also shows a display controller 526 that is coupled to the processor 510 and to a display 528. A speaker 536 may be coupled to the CODEC 534. The electronic device 500 may further include a modem 540 coupled to an antenna 542.

In a particular example, the processor 510, the memory 524, the display controller 526, the CODEC 534, and the modem 540 are included in or attached to a system-on-chip (SoC) device 522. Further, an input device 530 and a power supply 544 may be coupled to the SoC device 522. Moreover, in a particular example, as illustrated in FIG. 5, the display 528, the input device 530, the speaker 536, the microphone 538, the antenna 542, and the power supply 544 are external to the SoC device 522. However, each of the display 528, the input device 530, the speaker 536, the microphone 538, the antenna 542, and the power supply 544 can be coupled to a component of the SoC device 522, such as to an interface or to a controller.

The foregoing disclosed devices and functionalities may be designed and represented using computer files (e.g. RTL, GDSII, GERBER, etc.). The computer files may be stored on computer-readable media. Some or all such files may be provided to fabrication handlers who fabricate devices based on such files. Resulting products include wafers that are then cut into die and packaged into integrated circuits (or “chips”). The chips are then employed in electronic devices, such as the electronic device 500 of FIG. 5.

In conjunction with the described embodiments, a device (e.g., the device 100) includes first means (e.g., the first set of storage elements 104) for storing data and includes second means (e.g., the second set of storage elements 106) for storing data. The device further includes means (e.g., the bias circuit 142) for generating a test bias signal (e.g., the test bias signal 144) to bias the first means and the second means. The device further includes means (e.g., the sensor circuit 150) for receiving a first signal (e.g., the first signal 151) from at least a first storage element (e.g., the first storage element 106) of the first means in response to the test bias signal, for receiving a second signal (e.g., the second signal 152) from at least a second storage element (e.g., the second storage element 108) of the second means in response to the test bias signal, and for generating a third signal (e.g., the third signal 153). The third signal has a delay characteristic (e.g., the delay characteristic 158) indicating a wear difference between the first storage element and the second storage element.

In conjunction with the described embodiments, a device (e.g., the device 200 or the system 300) includes means (e.g., the first set of storage elements 104) for storing data and for receiving a supply voltage (e.g., the supply voltage 118). The device further includes means (e.g., the sensor circuit 250) for receiving a first signal (e.g., the first signal 204) from one or more storage elements (e.g., the first storage element 106) of the means for storing and for generating a second signal (e.g., the second signal 230). The second signal has a frequency (e.g., the frequency 232) that indicates a magnitude of the first signal. The device further includes means (e.g., the control circuit 114) for increasing the supply voltage in response to the frequency of the second signal.

As used herein, “coupled” may include communicatively coupled, electrically coupled, magnetically coupled, physically coupled, optically coupled, and combinations thereof. Two devices (or components) may be coupled (e.g., communicatively coupled, electrically coupled, or physically coupled) directly or indirectly via one or more other devices, components, wires, buses, networks (e.g., a wired network, a wireless network, or a combination thereof), etc. Two devices (or components) that are electrically coupled may be included in the same device or in different devices and may be connected via electronics, one or more connectors, or inductive coupling, as illustrative, non-limiting examples. In some implementations, two devices (or components) that are communicatively coupled, such as in electrical communication, may send and receive electrical signals (digital signals or analog signals) directly or indirectly, such as via one or more wires, buses, networks, etc.

The various illustrative logical blocks, configurations, modules, circuits, and algorithm steps described in connection with the examples disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

One or more operations of a method or algorithm described herein may be embodied directly in hardware, in a software module executed by a processor, or in a combination of the two. For example, one or more operations of the method 400 of FIG. 4 may be initiated, controlled, or performed by a field-programmable gate array (FPGA) device, an application-specific integrated circuit (ASIC), a processing unit such as a central processing unit (CPU), a digital signal processor (DSP), a controller (e.g., the controller 170), another hardware device, a firmware device, or a combination thereof. A software module may reside in random access memory (RAM), magnetoresistive random access memory (MRAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transitory storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal.

The previous description of the disclosed examples is provided to enable a person skilled in the art to make or use the disclosed examples. Various modifications to these examples will readily apparent to those skilled in the art, and the principles defined herein may be applied to other examples without departing from the scope of the disclosure. Thus, the present disclosure is not intended to be limited to the examples shown herein but is to be accorded the widest scope possible consistent with the principles and novel features as defined by the following claims.

What is claimed is:

1. A device comprising:
a first set of storage elements;
a second set of storage elements;
a bias circuit configured to generate a test bias signal to bias the first set of storage elements and the second set of storage elements; and
a sensor circuit configured to receive a first signal from at least a first storage element of the first set of storage elements in response to the test bias signal and to receive a second signal from at least a second storage element of the second set of storage elements in response to the test bias signal, the sensor circuit further configured to generate a third signal having a delay characteristic indicating a wear difference between the first storage element and the second storage element.

2. The device of claim 1, wherein the sensor circuit is further configured to determine aging of one or more transistors without accessing stored reference information.

3. The device of claim 1, further comprising a control circuit configured to provide a supply voltage to the first set of storage elements and the second set of storage elements and to increase the supply voltage in response to the delay characteristic satisfying a threshold.

4. The device of claim 1, wherein the bias circuit includes a digital-to-analog converter (DAC) circuit configured to receive a digital signal and to generate the test bias signal based on the digital signal.

5. The device of claim 4, wherein the sensor circuit is further configured to transition the third signal from a first value to a second value in response to a state change of the first storage element based on a first value of the digital signal at a first time.

6. The device of claim 5, wherein the sensor circuit is further configured to transition the third signal from the second value to the first value in response to a state change of the second storage element based on a second value of the digital signal at a second time after the first time.

7. The device of claim 1, wherein the sensor circuit includes an exclusive-or (XOR) circuit configured to generate the third signal.

8. The device of claim 1, further comprising:
a first bit line coupled to the first set of storage elements; and
a second bit line coupled to the second set of storage elements.

9. The device of claim 8, further comprising:
a first access transistor coupled to the first bit line and to the sensor circuit; and
a second access transistor coupled to the second bit line and to the sensor circuit.

10. The device of claim 1, further comprising:
a first complement bit line coupled to the first set of storage elements; and
a second complement bit line coupled to the second set of storage elements.

11. The device of claim 10, further comprising:
a third access transistor coupled to the first complement bit line and to the bias circuit; and
a fourth access transistor coupled to the second complement bit line and to the bias circuit.

12. The device of claim 1, wherein the wear difference indicates an amount of negative-bias temperature instability (NBTI) associated with one or more transistors of the first storage element.

13. A device comprising:
a set of storage elements configured to receive a supply voltage;
a sensor circuit coupled to the set of storage elements, the sensor circuit configured to receive a first signal from one or more storage elements of the set of storage elements and to generate a second signal having a frequency that indicates a magnitude of the first signal; and
a control circuit coupled to the set of storage elements, the control circuit configured to increase the supply voltage in response to the frequency of the second signal.

14. The device of claim 13, wherein the sensor circuit is further configured to determine aging of one or more transistors of the set of storage elements without accessing stored reference information.

15. The device of claim 13, further comprising:
a bit line coupled to the set of storage elements; and
a current mirror circuit of the sensor circuit, the current mirror circuit coupled to the bit line and configured to generate bias signals based on the first signal.

16. The device of claim 15, further comprising a current-starved ring oscillator circuit of the sensor circuit, the current-starved ring oscillator circuit configured to generate the second signal based on the bias signals.

17. The device of claim 13, wherein the frequency indicates a negative-bias temperature instability (NBTI) associated with one or more transistors of the one or more storage elements.

18. A method of operation of a device, the method comprising:
generating a first signal using at least one static random access memory (SRAM) storage element of a device;
generating a second signal using a reference SRAM storage element;
based on the first signal and the second signal, generating a third signal having a delay characteristic indicating aging of one or more transistors of the at least one SRAM storage element; and
based on the delay characteristic, increasing a supply voltage of the at least one SRAM storage element.

19. The method of claim 18, wherein the third signal is generated using an exclusive-or (XOR) circuit.

20. The method of claim 18, wherein the delay characteristic corresponds to a difference between a first transition of the first signal from a first value to a second value and a second transition of the second signal from the first value to the second value.
